(19) United States
(12) Patent Application Publication
(10) Pub. No.: US 2006/0257558 A1
(43) Pub. Date: Nov. 16, 2006

(54) Plasma polymerization of atomically modified surfaces

(76) Inventor: Hiroshi Nomura, Shorewood, MN (US)

Correspondence Address: ALTERA LAW GROUP, LLC, 6500 CITY WEST PARKWAY, SUITE 100, MINNEAPOLIS, MN, 55344-7704, US

(21) Appl. No.: 10/979,772

(22) Filed: Nov. 1, 2004

Related U.S. Application Data
(60) Provisional application No. 60/516,656, filed on Oct. 31, 2003.
(60) Provisional application No. 60/516,654, filed on Oct. 31, 2003.
(60) Provisional application No. 60/516,655, filed on Oct. 31, 2003.

(51) Int. Cl. C08J 7/18; B05D 5/12; C23C 16/00; B05D 5/06; H05H 1/24

(52) U.S. Cl. 427/162; 427/487; 427/58; 427/248.1; 427/569

(57) ABSTRACT

The invention is directed to a plasma polymerization method is which modifies the surface of plastic fibers which have been pre-treated with atomic oxygen texturing to generate micron dimension morphology on the distal end of the fiber. The plasma polymerization method causes a gaseous monomer to chemically modify the surface of the fiber without destroying the micron dimension topology that existed pre-polymerization.

### CROSS-REFERENCE TO RELATED APPLICATIONS

This application claims the benefit of U.S. Provisional Patent Application Ser. No. 60/516,656 filed Oct. 31, 2003 (Nomura, “Method and Apparatus for Body Fluid Analysis Using Surface-Textured Optical Materials”), U.S. Provisional Patent Application Ser. No. 60/516,654 filed Oct. 31, 2003 (Nomura, “Plasma Polymerization of Atomically Modified Surfaces”), and U.S. Provisional Patent Application Ser. No. 60/516,655 filed Oct. 31, 2003 (Shebuski et al., “Detection of Acute Myocardial Infarction Precursors”), which hereby are incorporated herein by reference thereto in their entirety.

### FIELD OF THE INVENTION

The present invention is directed generally to a non-destructive plasma polymerization process for modifying atomic oxygen modified textured surfaces which have micron dimension morphology.

### BACKGROUND

Recent technological breakthroughs have yielded atomic oxygen modified plastic substrates with surface texturing with micron dimension morphology. The resultant surface morphology has in some cases yielded steep ridges with heights on the order of about 5 microns and spacing between ridges on the order of a few microns. With these dimensions, it may be possible to separate whole blood, i.e., spatially filter the red blood cells (RBCs) from the blood plasma by taking advantage of the micron dimension morphology of these atomic oxygen textured surfaces given that RBCs are too large (typically on the order of about 7 to 8 microns) to geometrically fit into the valleys between the steep ridges. However, to realize functional biosensors, it would be advantageous if the textured surfaces could undergo a surface treatment which, for example, might modify the surface for attachment of analyte sensing chemistries, such as antibodies, and simultaneously not destroy (smooth out) the micron dimension morphology of the textured surface. There is a need for a non-destructive process to chemically modify the topology of textured surfaces with micron dimension morphology.

Plasma polymerization and treatment are processes to modify the surface of membrane materials to achieve specific functionality. Such surfaces may be modified to become wettable, non-fouling, slippery, crosslinked, reactive, reactable and/or catalytic. The plasma polymerization process is a chemical bonding technology in which a plasma is created at or near ambient temperatures in a modest vacuum, causing a gaseous monomer to chemically modify the surface of a substrate material. Polymers obtained by the plasma process are chemically and structurally similar to starting monomers, but there are differences. Analysis by X-ray photoelectron spectroscopy (XPS) indicates that plasma polymers form a network of highly branched and highly crosslinked segments. In addition, the mechanism of polymer formation and deposition combine to achieve excellent adhesion of the ultra-thin polymer layer to the substrate. As a result, gas plasma generated hydrophilic polymers are very stable in the presence of water, whereas commonly available hydrophilic polymers tend to readily dissolve in water.

In biosensor applications, affinitive materials can be prepared by plasma polymerization techniques. The development of bio-affinitive materials involves the selection of base materials, covalent coupling chemistry, and ligands. One feature of a plasma polymerization surface-modified composite sensor is its high reactivity and specific selectivity. It is standard practice to perform a blood analysis to separate plasma from whole blood via filtration techniques. This use of blood plasma eliminates common problems encountered when red blood cells (RBCs) are present in the sample, such as optical interference (light absorption and light scattering) and plasma volume displacement. The resulting measurement can be significantly different from those obtained directly on whole blood.

Plasma polymerization surface-textured composite membrane sensors separate blood plasma from whole blood with minimal complication, and allow the direct use of whole blood as the sample for blood analysis while reducing sample size. Although most biosensors have been designed and calibrated to be used with plasma, few have been built with the capability of separating plasma from a whole blood sample. The textured surfaces of biosensors modified by the plasma polymerization process will impart selectivity to exclude RBCs, thereby promoting a plasma/RBC separation which allows the plasma to penetrate into a reactive core layer. Current biosensors utilizing plasma modified surfaces are typically planar and the plasma polymerization process tends to remove surface irregularities and generate a smooth finished surface.

### SUMMARY OF THE INVENTION

In one particular embodiment of the present invention, a plasma polymerization method is described which modifies the surface of a plastic fiber which has been pre-treated with atomic oxygen texturing to generate micron dimension morphology on the distal end of the fiber. The plasma polymerization method causes a gaseous monomer to chemically modify the textured surface of the PMMA fiber without destroying the micron dimension morphology that existed prior to the polymerization.

In another embodiment of the present invention, a plasma polymerization method is described which modifies the surface of a planar film or sheet which has been pre-treated with atomic oxygen texturing to generate micron dimension morphology on the film or sheet. The plasma polymerization method causes a gaseous monomer to chemically modify the surface of the film or sheet without destroying the micron dimension topology that existed prior to polymerization.

The above summary of the present invention is not intended to describe each illustrated embodiment or every implementation of the present invention. The figures and the detailed description, which follow more particularly, exemplify these embodiments.

### BRIEF DESCRIPTION OF THE DRAWINGS

The invention may be more completely understood with the following detailed description of various embodiments of the invention in connection with the accompanying drawings, in which:

FIG. 1 schematically illustrates a system to perform plasma polymerization according to an embodiment of the present invention.

FIG. 2 schematically illustrates a side view of the system in FIG. 1 to perform plasma polymerization according to an embodiment of the present invention.

FIG. 3 shows a scanning electron micrograph (SEM) (magnified 10,000×) of an atomic oxygen textured plastic surface prior to plasma polymerization.

FIG. 4 shows a scanning electron micrograph (SEM) (magnified 10,000×) of an atomic oxygen textured plastic surface after plasma polymerization according to an embodiment of the present invention.

FIG. 5 schematically illustrates a side view of the system to perform the roll-to-roll plasma polymerization according to an embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

In accordance with the invention being disclosed herein, atomic oxygen surface-textured substrates are modified by the deposition of a plasma polymerizate on their surfaces from a glow discharge gas plasma. In a method of making these improved materials, a gas, or a blend of gases, is fed into an evacuated vacuum chamber. The gas, or blend of gases, is excited to a plasma state by a glow discharge maintained by application of energy in the form of, for example, an audio frequency, a microwave frequency or a radio frequency field. A suitable substrate is exposed to the glow discharge gas plasma, whereby exposed surfaces of the substrate are modified by deposition of a plasma polymerizate. The plasma polymerization process is non destructive to the atomic oxygen modified textured surfaces which have micron dimension morphology.

The biosensor may be an optical material, such as an optical fiber or optical membrane comprising a plastic or polymer material. The plastic or polymer optical material can be, for instance, polymethylmethacrylate (PMMA), polystyrene, polycarbonate, polyimide, polyamide, polyvinyl chloride (PVC), or polysulfone. The optical fiber comprises a tip which may be textured using an atomic oxygen process. While various surface texturing processes are available, plastic optical materials preferably are textured by etching with atomic oxygen. Generation of atomic oxygen can be accomplished by several known methods, including radio frequency, microwave, and direct current discharges through oxygen or mixtures of oxygen with other gases. Directed beams of oxygen such as by an electron resonance plasma beam source may also be utilized, accordingly as disclosed in U.S. Pat. No. 5,560,781, issued Oct. 1, 1996 to Banks et al., which is incorporated herein in its entirety by reference thereto. Techniques for surface texturing are described in U.S. Pat. No. 5,859,937, which issued Jan. 12, 1999, to Nomura, and which is incorporated herein in its entirety by reference thereto.

Atomic oxygen can be used to microscopically alter the surface morphology of polymeric materials in space or in ground laboratory facilities. For polymeric materials whose sole oxidation products are volatile species, directed atomic oxygen reactions produce surfaces of microscopic cones. However, isotropic atomic oxygen exposure results in polymer surfaces covered with lower aspect ratio sharp-edged craters. Isotropic atomic oxygen plasma exposure of polymers typically causes a significant decrease in water contact angle as well as altered coefficient of static friction. Atomic oxygen texturing of polymers is further disclosed and the results of atomic oxygen plasma exposure of thirty-three (33) different polymers, including typical morphology changes, effects on water contact angle, and coefficient of static friction, are presented in Banks et al., Atomic Oxygen Textured Polymers, NASA Technical Memorandum 106769, Prepared for the 1995 Spring Meeting of the Materials Research Society, San Francisco, Calif., Apr. 17-21, 1995, which hereby is incorporated herein in its entirety by reference thereto.

The general shape of the projections in any particular field is dependent upon the particulars of the method used to form them and on subsequent treatments applied to them. Suitable shapes include conical, ridge-like, pillared, box-like, and spike-like. While the projections may be arrayed in a uniform or ordered manner or may be randomly distributed, the distribution of the spacings between the projections preferably is fairly narrow with the average spacing being such as to exclude certain cellular components of blood such as the red blood cells from moving into the space between the projections. The projections function to separate blood components so that the analyte that reacts with the surface-resident agent is free of certain undesirable body fluid components. In some applications such as the ruling out of acute myocardial infarction using platelet activation markers, the spacings between the projections generally should be great enough to admit the platelets while excluding the red and white blood cells. Atomic oxygen texturing is discussed in more detail in the applications filed concurrently herewith entitled Detection of Acute Myocardial Infarction Biomarkers, which names Ronald J. Shebuski, Arthur R. Kydd, and Hiroshi Nomura as inventors, attorney docket number 1875.2-US-U1 and System and Apparatus for Body Fluid Analysis Using Surface Textured Optical Materials, listing inventor Hiroshi Nomura of Shorewood, Minn., attorney docket number 1875.1-US-U1 which are incorporated herein by reference in their entirety. As a result of atomic oxygen texturing of the tip, the surface of the optical tip includes a plurality of elongated projections. The projections are suitably spaced apart to exclude certain cellular components, such as red and white blood cells, of the body fluid sample, such as blood, from entering into the wells or valleys between the projections, while permitting the remaining part of the body fluid sample, which contains the analyte, to enter into those wells or valleys. Analytes/markers in the plasma, which are indicative of cellular and/or soluble platelet activation and coagulation activation, contacts or associates with the analyte specific chemistries on the surface of the elongated projections, whereupon the analyte and the analyte specific chemistry interact in a manner that is optically detectable. This permits almost instantaneous analysis of the available plasma component of blood. The analyte specific chemistries are attached to the textured surface by way of interacting (e.g., covalent or ionic bonding) with the functional carboxyl groups deposited on the surface during the plasma polymerization process. Activation of the carboxylated supports can be accomplished through use of carboiimides, which couple carboxyl groups to amines forming amide bonds. Carboiimides react, giving O-urea derivatives which enzymes or antibodies can couple via protein amine groups. Conversely, the immobilization can be brought about through the formation of amide bonds between carboxyl groups of proteins (enzymes, antibodies, etc.) and amino groups of the support.

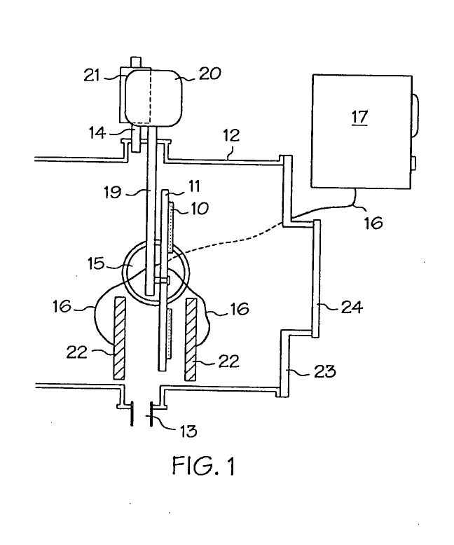

FIG. 1 illustrates an apparatus in which the plasma polymerization of the atomic oxygen surface textured substrate may be accomplished. An atomic oxygen textured substrate 10 is mounted on a rotating disk 11 within a vacuum chamber 12 having connected thereto an outlet port 13 to a vacuum source (not shown), an inlet port 14 for introduction of the monomer vapor, and an electrical port 15 for introduction of an electrical cable 16 from a frequency signal generator 17. The rotating disk 11 is driven by a shaft 19 connected to a drive source 20, such as a motor. The drive source 20 is preferably external to the vacuum chamber 12, with the drive shaft 19 penetrating a wall or port 18 on the vacuum chamber 12 via a mechanical seal. A monomer flow controller 21 is connected to the monomer vapor inlet port 14, to control the rate of monomer vapor delivery to the vacuum chamber 12. Electrode 22, connected to the signal generator 17, may be mounted either externally to the vacuum chamber 12, or internally within vacuum chamber 12, as shown in FIG. 1. Electrode 22 may be one or more electrodes, such as a pair of electrodes, as shown in FIG. 1. An access plate 23, optionally containing a view port 24, provides a means of access into the vacuum chamber 12.

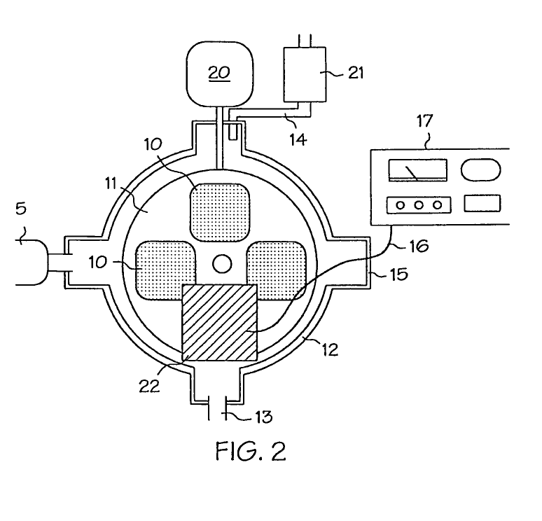

FIG. 2 shows a side view of the apparatus of FIG. 1, as seen from the direction of the access plate 23. Atomic oxygen textured substrates 10 are mounted on the rotating disk 11, which carries them between a pair of electrodes 22 (one shown) within vacuum chamber 12. A pressure transducer 25 is also shown, mounted on the vacuum chamber 12 by means of another port 26.

When a single electrode 22 is utilized, the frequency signal is transmitted to this electrode. When a pair of electrodes 22 is used, one electrode may be the signal-transmitting electrode and the other electrode may be a ground electrode. Electrode(s) 22 are preferably positioned so that a glow discharge gas plasma is produced in a region or zone within vacuum chamber 12 in which the substrate 10 to be plasma-treated is either located or passed through. In the apparatus as shown, a pair of electrodes 22 are positioned one on each side of the rotating disk 11, and substrates 10 mounted on the disk 11 are rotated through a glow discharge region located between the two electrodes 22. The walls of the vacuum apparatus 12 preferably consist either of glass or metal, or combinations of glass and metallic parts. When a metal is used rather than glass, a view port 24 is customarily placed in a wall of the vacuum chamber 12 to allow for visual observation and confirmation of the presence of a glow discharge during plasma processing.

The rotational method of exposing substrates to a gas plasma between the electrodes allows more than one atomic oxygen textured substrate to be exposed to essentially the same plasma treatment conditions. Other apparatus designs and other techniques for bringing an atomic oxygen textured substrate into contact with a gas plasma may be employed. For instance, a continuous, uninterrupted exposure of an atomic oxygen textured substrate to a gas plasma may be employed for a time sufficient to modify the surface of the substrate with a suitable deposit of a plasma polymerizate. The particular apparatus in FIGS. 1 and 2 is not to be taken as limiting in the practice of the invention. Variations in the design and operation of a gas plasma apparatus may be utilized, as would be evident to one skilled in the art. As an example, continuous sheeting of an atomic oxygen textured substrate may be processed by roll-to-roll movement of the sheeting through a zone of gas plasma, is within the scope of the invention, utilizing an apparatus designed for that purpose.

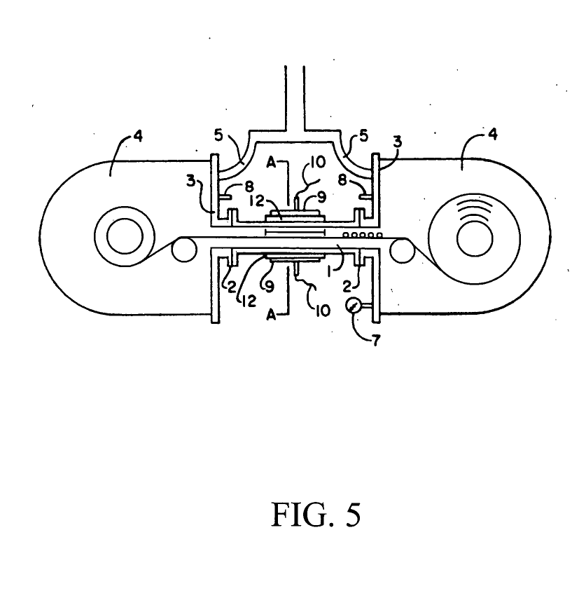

The roll-to-roll method is depicted schematically in FIG. 5. A roll-to-roll unit 500 is shown wherein reaction tunnel 1 is connected at each end by means of flange joints 2 to a pair of bell chambers having base plates 3 and movable bell housings 4. The bell housings 4 seal to the base plates 3 when the chambers are evacuated, but may otherwise be moved away for access to system components and workpieces in the chamber interiors. Provision is made for evacuating the system by means of vacuum ports 5 located on each of the base plates. The vacuum ports 5 are connected to a vacuum source (not shown) by means of a line that contains a valve 6 which is controlled by a pressure sensing monitor 7 so as to maintain system pressure at a level consistent with gas plasma treatment, i.e., normally in the range of 0.01 to 2 torr. Though not shown here, vacuum ports may also be individually equipped with on-off valves to allow evacuation through one bell chamber selectively rather than both bell chambers simultaneously. A reactive gas (e.g., polymerizable monomers), a mixture of reactive gases, or a mixture of reactive and nonreactive gases is fed through one or more inlet ports 8. Glow discharge electrodes 9 having electrical leads 10 extending therefrom are externally mounted to the reaction tunnel 1. During plasma treatment, the system is evacuated, reactive gas is fed to the system to a desired pressure level, glow discharge electrodes 9 are electrically activated to produce a gas plasma in the reaction tunnel 1, and the article to be treated is fed through the reaction tunnel from one bell chamber to the other. Though depicted as bell-shaped in FIG. 5, the bell housings 4 may be otherwise shaped, with appropriate configuring of the base plate for assembly and sealing purposes. The base plates 3 may be fixed to a track by means of permanent mountings, and the bell housings 4 are mounted to movable brackets that slide on the track. This allows the bell housings 4 to be easily moved away from the base plates 3 for access to system components and workpieces located inside the bell chambers. It is generally advantageous for system components located inside the bell chambers to be mounted to the base plates 3 rather than the movable bell housings 4. The mounting may be made directly to the base plate or indirectly made by means of a frame or scaffold anchored to the base plate.

As described above, the plasma polymerization process is amenable to both the rotational and roll-to-roll method of exposing substrates. In the rotational method the substrates are periodically being exposed to the gas plasma, whereas in the roll-to-roll method the substrates (in sheet form) pass through the plasma zone at a constant linear speed. In one embodiment of the rotational method, the gas plasma may be sustained by excitation power in the range of 10 to 50 watts and driven at a frequency in the range of 20 to 100 kilohertz (kHz) for approximately 1 to 30 minutes, preferably 2 to 10 minutes. Also, in this embodiment of the rotational method, the vacuum chamber environment may be in the range of 100 to 1,000 millitorr.

In the roll-to-roll method, the gas plasma may be sustained by excitation power in the range of 50 to 200 watts and driven at a frequency near 13.56 Megahertz (MHz). Also, in the roll-to-roll method the vacuum chamber environment may be set in the range of 200 to 1,000 millitorr. In the roll-to-roll method the substrate sheet may be passing through the plasma zone at a linear speed in the range of 0.1 to 10 cm/sec for a dwell time in the plasma of 1 to 120 seconds.

As an example of a method of making a plasma polymerized atomic oxygen textured substrate for use in genomic, immunoassay, or cardiac marker sensing in accordance with the present invention, one or more atomic oxygen textured substrates are mounted on rotating disk 11 in vacuum chamber 12. Vacuum chamber 12 is closed and may be evacuated to less than 1.0 torr, preferably to about 30 millitorr or less. A monomer vapor is introduced into vacuum chamber 12 generally in a continuous flow. Plasma system pressure is maintained at a preselected pressure level, typically 100 to 1,000 millitorr, through control of the monomer inflow rate and the vacuum outflow rate. Rotation of disk 11 is started, and a glow discharge is initiated through the monomer vapor by means of a signal transmitted from signal generator 17 through electrode pair 22. A plasma polymerizate forms on the surface or surfaces of the substrates 10 where the surfaces are exposed to the glow discharge gas plasma.

Unlike conventional polymerization, in the plasma process, several parameters should be controlled in order to obtain desired surface properties. The plasma excitation energy (watts) controls the degree of crosslinkage on substrate 10. Monomer flow rate (sccm) controls the deposition rate on substrate 10. The monomer molecular weight (gm) affects the atomic composition on substrate 10. Further, system pressure (mtorr) affects the functional group deposited on substrate 10. Exposure time (min.) controls the coating thickness on substrate 10. Polymerization mode (continuous, pulse, graft) relates to the uniformity and morphology on substrate 10.

The character (e.g., intensity, reactivity, radical, or ionized form) of the gas plasma may be controlled according to the composite plasma parameter W/FM where W is the power input to the gas plasma from the signal generator, F is the flow rate of the monomer gas/vapor, and M is the molecular weight of the particular monomer selected for plasma polymerization. The nature of the plasma polymerizate that is deposited is in turn controlled by the composite plasma parameter, but also reflects the nature of the polymerizable monomer or monomers fed to the gas plasma. In addition to this composite plasma parameter and to monomer selection, exposure time of the substrate 10 to the gas plasma is also preferably controlled. Additional control may be exercised by generating an intermittent glow discharge such that the plasma polymerizate deposited on a substrate 10 surface may have time to interact with the monomer vapor in the absence of glow discharge, such that some grafting of the monomer may be effected. Additionally, the resulting plasma polymerizate may be exposed to unreacted monomer vapor in the absence of a glow discharge as a post-deposition treatment, such that residual free radicals may be quenched.

Polymerizable monomers that may be used in the practice of the invention may comprise unsaturated organic compounds such as halogenated olefins, olefinic carboxylic acids and carboxylates, olefinic nitrile compounds, olefinic amines, oxygenated olefins and olefinic hydrocarbons. Such olefins include vinylic and allylic forms. The monomer need not be olefinic, however, to be polymerizable. Cyclic compounds such as cyclohexane, cyclopentane and cyclopropane are commonly polymerizable in gas plasmas by glow discharge methods. Derivatives of these cyclic compounds, such as 1,2-diaminocyclohexane, for instance, are also commonly polymerizable in gas plasmas. Particularly preferred are polymerizable monomers containing hydroxyl, amino or carboxylic acid groups. Of these, particularly advantageous results have been obtained through use of allylamine or acrylic acid. Mixtures of polymerizable monomers may be used. Additionally, polymerizable monomers may be blended with other gases not generally considered as polymerizable in themselves, such as argon, nitrogen and hydrogen.

Modification of substrates with selected monomers and varied coating thicknesses could make significant changes in surface functionality. Biofunctional plasma polymer surfaces may be classified as: 1) inert hydrophobic; 2) acidic-oxygen containing; and 3) basic nitrogen-containing functional groups. Attachment of functional groups or modification to inert surfaces will be carried out by plasma polymerization (graft, continuous mode) of monomers with five typical groups, as set forth in Table 1 below.

TABLE 1
Plasma Monomers

| | Functional Group | | Monomer |
|---|---|---|---|
| Functional | Acidic | —COOH | Acrylic acid (CH₂═CHCOOH) |
| | | —OH | Allyl alcohol (CH₂═CHCH₂OH) |
| | | —SH | Ethyl mercaptan (CH₃CH₂SH) |
| | Basic | —NH₂ | Allylamine (CH₂═CHCH₂NH₂) |
| | | | 1,2-Diaminocyclohexane |
| | | | (C₆H₁₀(NH₂)₂) |
| Inert | | | Tetrafluoroethylene (CF₂═CF₂) |
| | | | Hexamethyldisiloxane |
| | | | (CH₃)₃SiOSi(CH₃)₃ |
| | | | Methane (CH₄) |

The polymerizable monomers are preferably introduced into the vacuum chamber in the form of a vapor. Polymerizable monomers having vapor pressures less than 0.01 torr are not generally suitable for use in the practice of this invention. Polymerizable monomers having vapor pressures of at least 0.05 torr at ambient room temperature are preferred. Where monomer grafting to plasma polymerizate deposits is employed, polymerizable grafting monomers having vapor pressures of at least 1.0 torr at ambient conditions are particularly preferred.

The gas plasma pressure in the vacuum chamber 12 may vary in the range of from 0.01 torr to 2.0 torr, more preferably in the range of 0.05 to 1.0 torr. To maintain desired pressure levels in chamber 12, especially since monomer is being consumed in the plasma polymerization operation, there generally is continuous inflow of monomer vapor to the plasma zone, generally between 1 sccm to 200 sccm, preferably 2-100 sccm. When nonpolymerizable gases are blended with the monomer vapor, continuous removal of excess gases is accomplished by simultaneously pumping through the vacuum port 13 to a vacuum source. Since nonpolymerizable gases may result from glow discharge gas plasmas, it is advantageous to control gas plasma pressure at least in part through simultaneous vacuum pumping during the plasma polymerizate deposition process on a substrate 10.

The glow discharge through the gas or blend of gases in the vacuum chamber 12 may be initiated by means of an audio frequency, a microwave frequency or a radio frequency field transmitted to or through a region or zone in the vacuum chamber 12. Particularly preferred is the use of a radio frequency (RF) discharge, transmitted through a spatial zone in the vacuum chamber 12 by an electrode 16 connected to an RF signal generator 17. A more localized and intensified gas plasma is attained by means of an electrode pair 22, whereas a more diffuse gas plasma is a result of a single electrode. A broad range of RF signal frequencies from about may be used to excite and maintain a glow discharge through the monomer vapor. In commercial scale usage of RF plasma polymerization, an assigned radio frequency of 13.56 MHz may be desirable to avoid potential radio interference problems.

The glow discharge may be continuous, or it may be intermittent during plasma polymerizate deposition. A continuous glow discharge may be employed, or exposure of a substrate surface 10 to the gas plasma may be intermittent during the overall polymerizate deposition process. In addition, both a continuous glow discharge and a continuous exposure of a substrate surface 10 to the resulting gas plasma for a desired overall deposition time may be employed. The plasma polymerizate that deposits onto the atomic oxygen textured substrate 10 generally will not have the same elemental composition as the incoming polymerizable monomer (or monomers). During the plasma polymerization, some fragmentation and loss of specific elements or elemental groups naturally occurs. Thus, in the plasma polymerization of allylamine, nitrogen content of the plasma polymerizate is typically lower than would correspond to pure polyallylamine. Similarly, in the plasma polymerization of acrylic acid, carboxyl content of the plasma polymerizate is typically lower than would correspond to pure polyacrylic acid. Exposure time to either of these unreacted monomers in the absence of a gas plasma, as through intermittent exposure to a glow discharge, allows for grafting of the monomer to the plasma polymerizate, thereby increasing the level of the functional group (i.e., amine or carboxylic acid) in the final deposit. Time intervals between gas plasma exposure and grafting exposure can be varied from a fraction of a second to several minutes to achieve the desired polymer thickness, using for example the rotational method illustrated in FIG. 1 and FIG. 2.

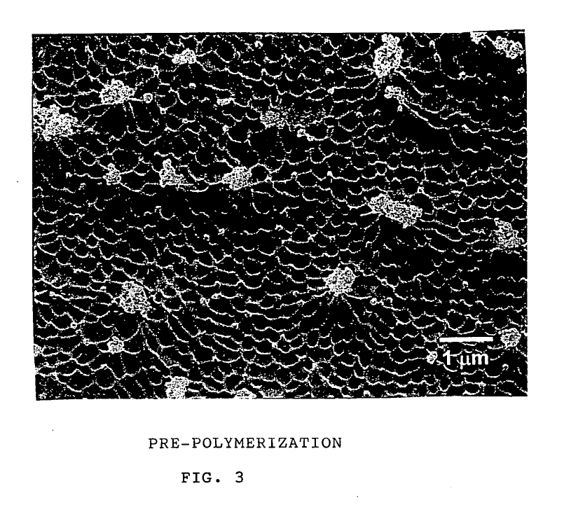

FIG. 3 shows a scanning electron micrograph (SEM) of an atomic oxygen textured plastic surface prior to plasma polymerization. The substrate material is the distal end of a polymethyl methacrylate (PMMA) plastic optical fiber supplied by the Mitsubishi Rayon Co. (ESKA Optical Fiber Division) part # CK-120. The fiber diameter is 3 mm and the scanning electron micrograph is at 10,000 times magnification. The atomic oxygen texturing of the PMMA fiber distal end was performed at a fluence level which yielded 3.9×10²⁰ atoms/cm².

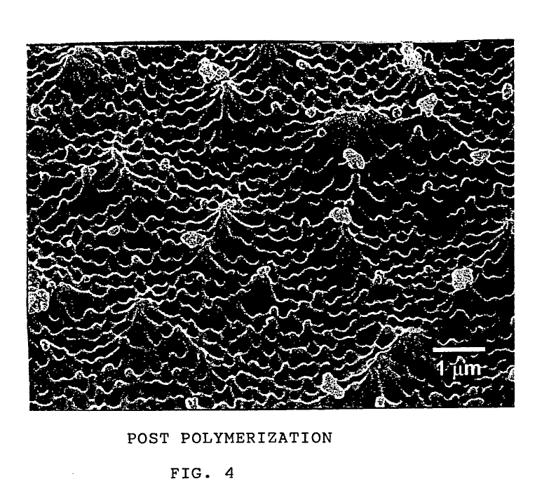

FIG. 4 shows a scanning electron micrograph (SEM) of the same atomic oxygen textured plastic PMMA fiber shown in FIG. 3 after plasma polymerization according to an embodiment of the present invention. The plasma polymerization was carried out with a methane/acrylic acid mixture injected into the vacuum chamber at 400 millitorr, as set forth below in Example 1. The RF power was set to 100 watts throughout the deposition, and the deposition time was approximately 60 seconds. FIG. 4 is also at 10,000 times magnification, but the image shows a different region of the plastic PMMA fiber distal end-face than FIG. 3. However, as can be seen in FIG. 4, the pre-polymerization surface morphology survived the plasma polymerization step.

Plasma polymer surfaces can be evaluated for stability (i.e., shelf life) based on surface analysis. Scanning Electron Microscopy (SEM), Fourier Transfer Infra-Red (FTIR), and X-ray Photoelectron Spectroscopy (XPS, ESCA) can be used to determine the change of surface atomic compositions, surface morphology and surface functionality. In addition, dye binding (ion exchange capacity) can be used to evaluate stability. Dye binding (ion exchange capacity) measurements can be performed. The density of acidic functional groups (such as carboxyl) will be determined using a positive-charge dye, Toluidine Blue (TB). The density of basic functional groups (such as amines) will be determined using a negative-charge dye, Bromthymol Blue (BTB). Measurements can be made by a spectrophotometer at 626 nm for TB and at 612 nm for BTB.

Plasma polymer surfaces are relatively stable if proper plasma conditions are applied. Dye binding capacities of several plasma modified surfaces stored for more than six months were found to be essentially unchanged.

TABLE 2
Stability of Plasma Polymer Surface (Ion Exchange Capacity)

| | | | |
|---|---|---|---|
| | Density of | Density of | |
| | Functional Group | Functional Group | |
| | (nmol/cm²) at | (nmol/cm²) after | Interval |
| Materials | present 4/95) | coated | (Months) |

Carboxyl Group (—COOH)

| | | | |
|---|---|---|---|
| Nylon Membrane A | 927 | 932 | 8 |
| Nylon Membrane B | 854 | 901 | 8 |
| Carboxyl Hollow Fiber | 30.3 | 24.3 | 22 |
| Membrane | | | |
| Nylon Bead | 303 | 415 | 8 |
| Polystyrene Beads | 16.9 | 2.4 | 8 |

Amine group (—NH₂)

| | | | |
|---|---|---|---|
| Polypropylene Hollow | 9.54 | 5.6 | 21 |
| Fiber Membrane | | | |
| Polystyrene Beads | 6.4 | 1.7 | 8 |

### EXAMPLE 1

The tip of an optic fiber (ESKA-CK120, core: polymethyl methacrylate, clad: fluorinated polymer, diameter; 3 mm, Mitsubishi Rayon Co.) was exposed to atomic oxygen effective fluence of 3.9×10²⁰ atoms/cm². The textured surface is shown in scanning electron micrograph (SEM) FIG. 3. A plasma co-polymer of acrylic acid-methane was deposited on the atomic oxygen textured optic fiber surface. Monomers were introduced to the reaction chamber by gas flow controller for methane at 54.4 sccm (standard temperature and pressure per cubic centimeter) and the flow rate of acrylic acid was controlled by a needle valve connected to evaporation jar at 14.9 sccm. System pressure was controlled at 400 millitorr by an adaptive pressure controller with control butterfly valves. Plasma glow was initiated and sustained at 100 watts (13.56 MHz). Plasma glow zone was 15 cm which is equal to the electrode length. The optical fiber was attached on the support film, e.g. polyethylene Terephthalate (PET), and traveled through the plasma zone at 0.25 cm/sec, with a resulting resident time of 60 seconds in the plasma zone. As shown in the SEM in FIG. 4, the structure of the atomic oxygen texture was kept intact with the plasma co-polymer deposition.

### EXAMPLE 2

The tip of an optic fiber (ESKA-CK120, core: polymethyl methacrylate, clad: fluorinated polymer, diameter; 3 mm, Mitsubishi Rayon Co.) was exposed to atomic oxygen effective fluence of 3.82×10²¹ atoms/cm² (Sample #1), 1.43 ×10²¹ atoms/cm² (Sample #2), and 1.07×10²¹ atoms/cm² (Sample #3), respectively. Sample #3 was masked with salt particles. The textured surface is shown in scanning electron micrograph (SEM) FIG. 3. A plasma polymer of acrylic acid was deposited on the atomic oxygen textured optic fiber surface. PET film and untextured optic fiber are also modified as controls. Argon gas was used as a co-existing inert gas. Gaseous flow rates were 115.2 sccm (cm³ (STP)/minute) for argon and 3 sccm (cm³ (STP)/minute) for acrylic acid, respectively. System pressure was 800 millitorr and RF power was 30 watts at 50 kHz. Plasma discharge time was for 2 minutes. Total polymer deposition was 1800 angstroms (Å). The deposition rate was measured with a thin film thickness and rate monitor and thickness was normalized by density=1.0 grams/cm³. The functional density of carboxyl function groups were determined with a positive charge dye, Toluidine Blue (measured at 626 nm in 0.01 N HCl) as listed in Table 1. PET film is selected as control because of an inert surface. PMMA (Polymethyl methaacrylate) has some negative charge and atomic oxygen textured surfaces have non characterized negatively charged sites which is relatively large amount in the range 78 to 150 by atomic oxygen. A plasma polymer of acrylic acid replaced the such non characterized site with a carboxyl function group and increased the functional density. Because maximum population of Toluidine blue is calculated to be 1.46/nm² (Stokes' Radius: 4.45 Å) on a planar surface, for PET film surface, plasma deposition create about 8 layers of carboxyl function groups and about 28 layers for PMMA non-textured optic fiber. PMMA surface is more reactive than PET for acrylic acid monomer. The textured surface of the optical fiber obtained 3 to 4 times higher density compared to non-textured optic fiber and the density of function group (such as carboxyl groups) of 120 to 165 (1/nm²) is extremely high and very advantageous for sensor miniaturization.

TABLE 3
Density of Carboxyl Functional Group

| | | | |
|---|---|---|---|
| | Functional Group | Number of - | (A) - |
| | Concentration | COOH group | control |
| Sample | (nmol/cm²) | (A) (1/nm²) | (1/nm²) |

PET film

| | | | |
|---|---|---|---|
| Control | 0.62 | 4 | 0 |
| Modified Control | 2.74 | 16 | 12 |

Optic fiber

| | | | |
|---|---|---|---|
| Control | 10.6 | 63 | 0 |
| AO textured S1 | 28.0 | 168 | 105 |
| AO textured S2 | 23.6 | 141 | 78 |
| AO textured S3 | 35.5 | 213 | 150 |
| Modified Control | 17.5 | 105 | 42 |
| Modified AO textured S1 | 30.6 | 183 | 120 |
| Modified AO textured S2 | 36.3 | 218 | 155 |
| Modified AO textured S3 | 37.9 | 227 | 164 |

### EXAMPLE 3

Plasma co-polymer of acrylic acid-methane was deposited on the atomic oxygen textured optic fiber surface, as set forth in Example 2. Monomers were introduced to a reaction chamber by gas flow controller for methane at 36 sccm (cm³ (STP)/minute). The flow rate of acrylic acid was controlled by a needle valve connected to evaporation jar at 4 sccm (cm³ (STP)/minute). System pressure was controlled at 170 millitorr. RF power was 20 watts at 50 kHz. Discharge time was 10 minutes. Total polymer deposition was 7000 angstroms (Å). Even with the thicker deposition layer the effectiveness of functional group density was saturated at the level of 150 (1/nm²).

TABLE 4
Density of Carboxyl Functional Group

| | Functional Group | Number of - |
|---|---|---|
| | Concentration | COOH group (A) |
| Sample | (nmol/cm²) | (1/nm²) |
| Control | 0.0 | 0 |
| Modified AO textured S1 | 27.6 | 166 |
| Modified AO textured S2 | 23.7 | 142 |
| Modified AO textured S3 | 26.3 | 158 |

The sensor geometries of both the fiber optic and membrane configuration are described in U.S. patent applications filed concurrently herewith entitled, “System and Apparatus For Body Fluid Analysis Using Surface-Textured Optical Materials”, by inventor Hiroshi Nomura, and methods and devices to detect heart attack precursors in U.S. patent application entitled “Detection of Acute Myocardial Infarction Biomarkers”, by inventors Ronald Shebuski, Arthur Kydd and Hiroshi Nomura as attorney docket numbers 1875.0001-US-U1 and 1875.0002-US-U1 respectively, both of which are incorporated herein by reference in its entirety.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices.

We claim:

1. A method for manufacturing a biosensor from an optical material body, comprising:
a) atomic oxygen etching an optical material body to produce a surface-textured area;
b) subjecting the surface-textured optical material body to a vacuum;
c) applying a monomer gas vapor to the optical material body; and
d) discharging energy through the monomer gas vapor to initiate polymerization of the monomer gas on the surface-textured area.

2. The method of claim 1 wherein the monomer gases comprise methane acrylic acid, allyl alcohol, ethyl mercaptan, allylamine, diaminocyclohexane, hexamethyldisiloxane, or tetrafluoroethylene.

3. The method of claim 1 wherein the monomer gas comprises methane acrylic acid.

4. The method of claim 1 wherein the discharging energy comprises radio frequency (RF), microwave, or audio frequency energy.

5. The method of claim 1 wherein the discharging energy is between 50 and 200 watts.

6. The method of claim 5 wherein the discharging energy is applied at a frequency of about 13.56 megahertz.

7. The method of claim 5 wherein the vacuum is between 200 and 1000 millitorr.

8. The method of claim 1 wherein the discharging energy is between 10 and 50 watts.

9. The method of claim 8 wherein the discharging energy is applied at a frequency between 20 and 100 KiloHertz.

10. The method of claim 8 wherein the vacuum is between 100 and 1000 millitorr.

11. The method of claim 1 wherein the optical material body is the distal end of an optical fiber.

12. The method of claim 1 wherein the optical material body is a plurality of distal ends of optical fibers.

13. The method of claim 1 wherein the optical material body is the lateral surface of an optical fiber.

14. The method of claim 1 wherein the optical material body is a plurality of lateral surfaces of optical fibers.

15. The method of claim 1 wherein the optical material body is a planar polymer surface.

16. The method of claim 1 wherein the optical material body comprises polymethyl methacrylate (PMMA), polystyrene, polycarbonate, polyimide, polyamide, polyvinyl chloride (PVC), or polysulfone.

17. A method for applying a plasma polymerization treatment to an optical material body having a surface-textured area, comprising:
a) placing the optical material body in a vacuum chamber
b) introducing monomer gases into the vacuum chamber;
c) activating glow discharge electrodes to produce a plasma glow;
d) discharging energy through the monomer gas vapor to produce a gas plasma;
e) exposing the surface-textured area of the optical material body to the gas plasma to initiate polymerization; and
f) depositing a polymerizate on the surface-textured area of the optical material body.

18. The method of claim 17 wherein the monomer gas comprises methane acrylic acid.
